(19) United States
(12) Patent Application Publication
(10) Pub. No.: US 2026/0318985 A1
(43) Pub. Date: Oct. 15, 2026

(54) AUTOMATED TESTING METHOD AND SYSTEM IMPLEMENTING THE SAME

(71) Applicant: Alpha Networks Inc., Hsinchu (TW)

(72) Inventors: Chien-Hsiang CHEN, Hsinchu (TW); Shih-Fang AO, Hsinchu (TW); Jen-Hung YANG, Hsinchu (TW)

(73) Assignee: Alpha Networks Inc., Hsinchu (TW)

(21) Appl. No.: 19/282,678

(22) Filed: Jul. 28, 2025

(30) Foreign Application Priority Data
Apr. 14, 2025 (TW) 114114059

(51) Int. Cl. G01R 31/28; G08B 29/04

(52) U.S. Cl. CPC G01R 31/2829; G01R 31/2834; G08B 29/04

(57) ABSTRACT

A method executed by a system for performing tests on a DUT is provided. The DUT includes an infrared sensing unit. The system includes a robotic arm device and a processing unit. The method includes the processing unit controlling the robotic arm device to move, such that a heat source is moved within a sensing range of the infrared sensing unit, determining whether the DUT has received a trigger signal from the infrared sensing unit, generating a primary test result indicating test failure or success, and generating and outputting a test report that includes the primary test result.

### CROSS-REFERENCE TO RELATED APPLICATION

This application claims priority to Taiwanese Invention Patent Application No. 114114059, filed on Apr. 14, 2025, the entire disclosure of which is incorporated by reference herein.

### FIELD

The disclosure relates to an automated testing method and a system implementing the same, and more particularly to a method for automatically testing a device under test (DUT) and a system implementing the same.

### BACKGROUND

In recent years, intelligence and automated electronic devices are continuously being improved. For example, passive infrared (PIR) sensors have been widely used in smart home electronic devices and security monitoring fields. PIR sensors are configured to detect changes in infrared radiation in the surrounding environment to determine whether a moving object is present, and play an important role in applications such as intrusion alarm systems and automatic lighting control.

A conventional method for testing a PIR sensor is performed through manual actions (e.g., by a user waving his/her hand in front of the PIR sensor) and is therefore inefficient and may be performed under unstable testing conditions.

### SUMMARY

Therefore, an object of the disclosure is to provide an automated testing method and a system that can alleviate at least one of the drawbacks of the prior art.

According to an aspect of the disclosure, an automated testing method is executed by a system for performing tests on a device under test (DUT). The DUT includes an infrared sensing unit and a control unit. The system includes a robotic arm device, a storage medium that stores a path dataset, and a processing unit that is electrically connected to the storage medium and the robotic arm device, and that is adapted to be electrically connected to the control unit. The robotic arm device includes an arm portion that is configured to be controlled by the processing unit to move, and an end portion that is disposed on the arm portion so as to be driven by the arm portion and that includes a heat source. The method includes steps of: A) the processing unit executing a testing procedure for testing the DUT, wherein the testing procedure includes sub-steps of a1) controlling the arm portion to move based on the path dataset, such that the heat source of the end portion is moved within a sensing range of the infrared sensing unit, a2) receiving status information that is generated by the control unit, and determining, based on the status information, whether the control unit has received a trigger signal from the infrared sensing unit indicating that the infrared sensing unit has sensed an object, a3) in response to determining that the control unit has not received the trigger signal, generating a primary test result indicating test failure, and storing the primary test result in the storage medium, and a4) in response to determining that the control unit has received the trigger signal, generating the primary test result indicating test success, and storing the primary test result in the storage medium; and B) after the testing procedure has ended, the processing unit generating and outputting a test report that includes the primary test result.

According to another aspect of the disclosure, a system for automated testing of a device under test (DUT) is provided. The DUT includes an infrared sensing unit and a control unit. The system includes a processing unit, a storage medium, and a robotic arm device. The processing unit is configured to be electrically connected to the control unit. The storage medium is electrically connected to the processing unit and stores a path dataset. The robotic arm device is electrically connected to the processing unit, and includes an arm portion that is configured to be controlled by the processing unit to move, and an end portion that is disposed on the arm portion so as to be driven by the arm portion, and that includes a heat source. The processing unit is configured to execute a testing procedure for testing the DUT by performing steps of: a1) controlling the arm portion to move based on the path dataset, such that the heat source of the end portion is moved within a sensing range of the infrared sensing unit, a2) receiving status information that is generated by the control unit, and determining, based on the status information, whether the control unit has received a trigger signal from the infrared sensing unit indicating that the infrared sensing unit has sensed an object, a3) in response to determining that the control unit has not received the trigger signal, generating a primary test result indicating test failure, and storing the primary test result in the storage medium, and a4) in response to determining that the control unit has received the trigger signal, generating the primary test result indicating test success, and storing the primary test result in the storage medium; and the processing unit is further configured to, after the testing procedure has ended, generate and output a test report that includes the primary test result.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic diagram illustrating a system for automated testing of a device under test (DUT), the DUT, and a user-end device according to a first embodiment of the disclosure.

FIG. 2 is a block diagram illustrating the system, the DUT and the user-end device according to the first embodiment of the disclosure.

FIG. 3 is a flow chart illustrating an automated testing method according to the first embodiment of the disclosure.

FIG. 4 is a flow chart illustrating sub-steps of the automated testing method according to the first embodiment of the disclosure.

FIG. 5 is a schematic diagram illustrating the system for automated testing of the DUT, the DUT and the user-end device according to a second embodiment of the disclosure.

FIG. 6 is a block diagram illustrating the system, the DUT and the user-end device according to the second embodiment of the disclosure.

FIG. 7 is a flow chart illustrating the automated testing method according to the second embodiment of the disclosure.

FIG. 8 is a flow chart illustrating sub-steps of the automated testing method according to the second embodiment of the disclosure.

FIG. 9 is a schematic diagram illustrating the system for automated testing the DUT, the DUT and the user-end device according to a fourth embodiment of the disclosure.

FIG. 10 is a block diagram illustrating the system, the DUT and the user-end device according to the fourth embodiment of the disclosure.

FIG. 11 is a flow chart illustrating the automated testing method according to the fourth embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Throughout the disclosure, the term “electrically connected to” may refer to coupling or a direct connection among a plurality of pieces of electrical apparatus/devices/equipment via an electrically conductive material (e.g., an electrical wire or a semi-conducting material), or an indirect connection between two pieces of electrical apparatus/devices/equipment via another one or more pieces of apparatus/devices/equipment, or wireless communication technology (e.g., Wi-Fi, Bluetooth®, or electromagnetic induction).

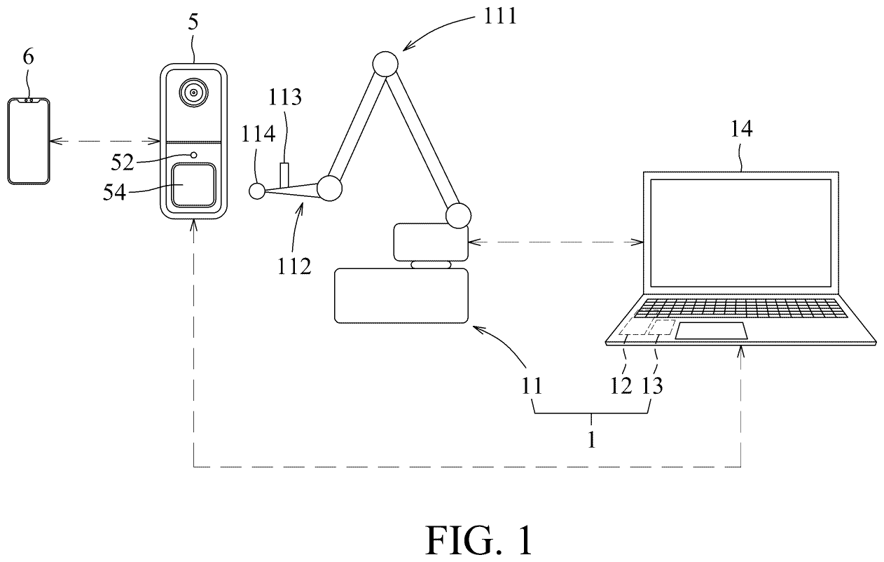

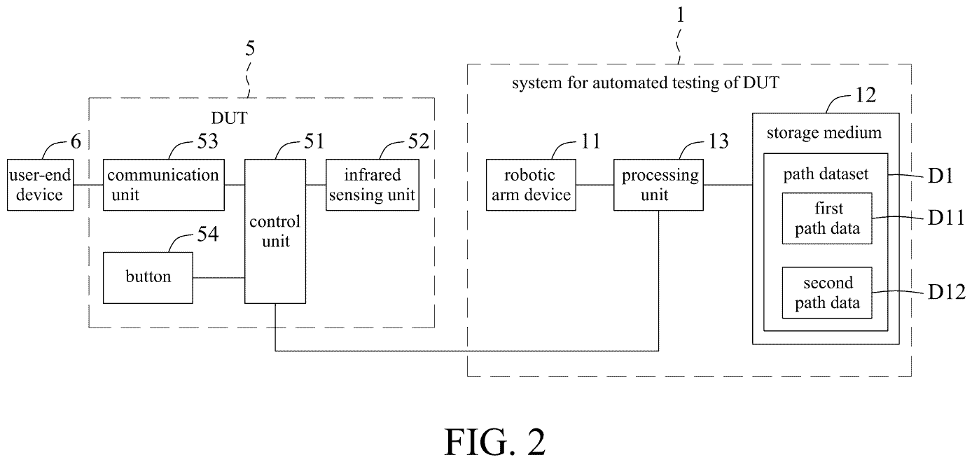

Referring to FIGS. 1 and 2, according to a first embodiment of the disclosure, a system 1 for automated testing of a device under test (DUT) 5 is configured to test whether an infrared sensing function and a button function of the DUT 5 are operating normally.

In this embodiment, the DUT 5 is a smart doorbell device, and includes a control unit 51, and an infrared sensing unit 52, a communication unit 53 and a button 54 that are electrically connected to the control unit 51.

The control unit 51 may be, for example, a combination of a central processing unit (CPU) and a microcontroller unit (MCU), and is configured to be switched between multiple operation modes. In one example, the operation modes include a normal operation mode and a power-saving mode. When the control unit 51 is operating in the normal operation mode, the control unit 51 is configured to continuously determine whether the infrared sensing unit 52 has sensed an object and whether the button 54 has been pressed. When the control unit 51 is operating in the power-saving mode, the CPU of the control unit 51 temporarily stops operating, and the MCU of the control unit 51 operates in a manner such that a power consumption of the MCU is reduced. In one example, when operating in the power-saving mode, the MCU of the control unit 51 lowers an operating frequency or suspends certain operations that would be performed in the normal operation mode (e.g., reducing frequency of or suspending the determination of whether the button 54 has been pressed).

The infrared sensing unit 52 may be a passive infrared (PIR) sensor that is configured to generate and output a trigger signal to the control unit 51 upon detecting a moving object (e.g., a human body that is moving). The control unit 51 is configured to, when operating in the power-saving mode, switch from the power-saving mode to the normal operation mode upon receiving the trigger signal. The control unit 51 is further configured to, when operating in the normal operation mode, remain operating in the normal operation mode upon receiving the trigger signal (i.e., not switching operation modes).

The communication unit 53 may be a video communication module that uses a Session Initiation Protocol (SIP), and is configured to establish a communication connection with a user-end device 6.

The button 54 is configured to receive an input via depression (e.g., from an operator), and to generate and output a press signal to the control unit 51 upon receiving the input. The control unit 51 is further configured to, upon receiving the press signal when operating in the normal operation mode, generate a communication request, and transmit the communication request to the user-end device 6 through the communication unit 53. The user-end device 6 may be, for example, a mobile phone, or an indoor intercom that is paired with a smart doorbell device (i.e., the DUT 5). The communication request is for requesting the user-end device 6 to permit the communication connection (e.g., a real-time audio-video communication) to be established with the DUT 5, so that the communication unit 53 is allowed to communicate with the user terminal 6.

The system 1 includes a robotic arm device 11, a storage medium 12, and a processing unit 13 that is electrically connected to the storage medium 12 and the robotic arm device 11.

The robotic arm device 11 includes an arm portion 111 that is configured to be controlled by the processing unit 13 to move, and an end portion 112 that is disposed on the arm portion 111 so as to be driven by the arm portion 111. In this embodiment, the end portion 112 includes a heat source 113 and a press member 114 that is made of a soft material with elasticity. Specifically, in this embodiment, the heat source 113 is a ceramic heating element that is configured to convert electrical energy into thermal energy, and the press member 114 is a foam block with a spherical shape. In other embodiments, the heat source 113 may be other electric heating elements such as a resistive element or a heating film that are configured to generate heat upon receiving electricity. In other embodiments, the press member 114 may be implemented as a sponge block, a rubber block, a silicone block, a thermoplastic elastomer (TPE), or other soft materials with elasticity.

The system 1 is disposed such that the robotic arm device 11 is placed at a test position that is adjacent to the DUT 5. When the robotic arm device 11 is at the test position, the end portion 112 of the robotic arm device 11 may be driven by the arm portion 111 to approach the infrared sensing unit 52 of the DUT 5 and/or to contact or press the button 54.

In one embodiment, the robotic arm device 11 is designed with a size and a weight that allow for high mobility. For example, a height of the robotic arm device 11 is approximately the same as a height of the DUT 5 (e.g., a smart doorbell). As such, the robotic arm device 11 and the DUT 5 may be simultaneously accommodated in a thermostatic testing device 15 (i.e., a constant temperature chamber or a temperature control chamber). To describe in further detail, the thermostatic testing device 15 occupies a small space. For example, a volume of the thermostatic testing device 15 is less than 100 liters. Since the robotic arm device 11 and the DUT 5 may be simultaneously accommodated in the thermostatic testing device 15, functions of the DUT 5 may be tested under different environmental temperatures controlled by the thermostatic testing device 15.

In this embodiment, the processing unit 13 and the storage medium 12 are integrated into a portable electronic device 14 (e.g., a laptop). The processing unit 13 may be a processor implemented as an integrated circuit that has functions of data processing and instruction transmission/reception, and is adapted to be electrically connected to the control unit 51 of the DUT 5 through a connection port and a transmission line (both are not shown) of the portable electronic device 14. In some embodiments, the processing unit 13 may be an electrical component that includes a processor and a circuit board, or a collection of multiple processors. In some embodiments, the processing unit 13 may be electrically connected to the control unit 51 of the DUT 5 through Bluetooth® or other wireless communication standards. The storage medium 12 may be implemented by one or more data storage devices (e.g., a hard disk drive) for storing digital data. In some embodiments, the storage medium 12 may be a collection of multiple storage devices of the same or different types, such as random access memory (RAM), read only memory (ROM), programmable ROM (PROM), flash memory, etc.

The storage medium 12 stores a path dataset D1. The path dataset D1 is readable by the processing unit 13 so that the processing unit 13 may control a moving path, which may be indicated by moving distances and moving directions, of the arm portion 111 of the robotic arm device 11 based on the path dataset D1.

In this embodiment, the path dataset D1 includes first path data D11 and second path data D12. The first path data D11 corresponds to a first path, and is used by the processing unit 13 for controlling the arm portion 111 of the robotic arm device 11 to drive the end portion 112 to move along the first path, such that the heat source 113 is moved within a sensing range of the infrared sensing unit 52. The second path data D12 corresponds to a second path, and is used by the processing unit 13 for controlling the arm portion 111 of the robotic arm device 11 to drive the end portion 112 to move along the second path that is a continuation of the first path (i.e., a beginning of the second path is connected to an end of the first path), such that the press member 114 of the end portion 112 is moved to press the button 54 of the DUT 5.

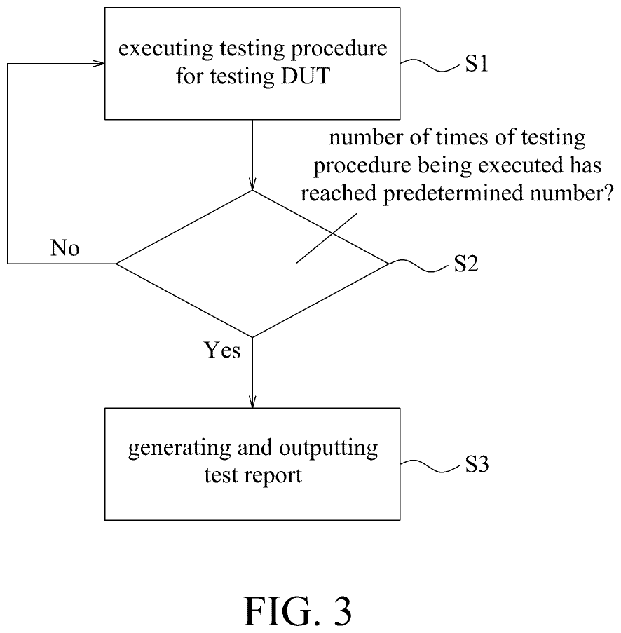

Referring further to FIG. 3, an automated testing method for performing tests on the DUT 5 according to the first embodiment is provided. The automated testing method is to be executed by the system 1 when the robotic arm device 11 is at the test position, and a flow of the method includes steps S1 to S3.

In step S1, the processing unit 13 executes a testing procedure for testing the DUT 5.

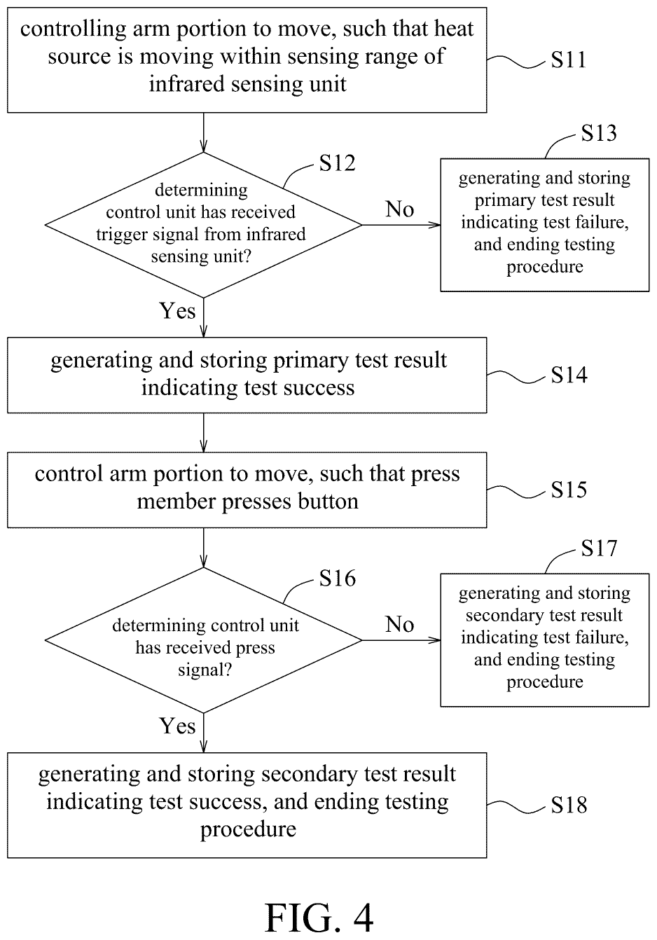

Referring further to FIG. 4, the testing procedure of the first embodiment includes sub-steps S11 to S18.

In sub-step S11, the processing unit 13 controls the arm portion 111 to move based on the first path data D11 of the path dataset D1, such that the arm portion 111 drives the heat source 113 of the end portion 112 to move along the first path within the sensing range of the infrared sensing unit 52. As such, the system 1 is able to use the heat source 113 on the robotic arm device 11 to simulate a human body moving in front of the infrared sensing unit 52.

In sub-step S12, the processing unit 13 receives status information that is generated by the control unit 51, and determines, based on the status information, whether the control unit 51 has received the trigger signal from the infrared sensing unit 52 indicating that the infrared sensing unit 52 has sensed an object.

Specifically, the status information is system output information of the DUT 5, and includes a CPU operating record that is able to be transferred via a CPU console (not shown) of the DUT 5 to the portable electronic device 14 for display and an MCU operating record that is able to be transferred via an MCU console (not shown) of the DUT 5 to the portable electronic device 14 for display. In this embodiment, the processing unit 13 determines whether the control unit 51 has received the trigger signal by determining whether an infrared trigger message has been logged in the MCU operating record within a first time period. The first time period is a time period during which the processing unit 13 controls the arm portion 111 to move based on the first path data D11. When the processing unit 13 determines that the infrared trigger message has been logged in the MCU operating record within the first time period, the processing unit 13 determines that the control unit 51 has received the trigger signal, and proceeds to perform sub-step S14. Otherwise, when the processing unit 13 determines that the infrared trigger message has not been logged in the MCU operating record within the first time period, the processing unit 13 determines that the control unit 51 has not received the trigger signal, and proceeds to perform sub-step S13.

In sub-step S13, in response to determining that the control unit 51 has not received the trigger signal, the processing unit 13 generates a primary test result indicating test failure of the infrared sensing unit 52 (which means that the infrared sensing unit 52 has failed the testing), stores the primary test result in the storage medium 12, and ends the testing procedure.

In sub-step S14, in response to determining that the control unit 51 has received the trigger signal, the processing unit 13 generates the primary test result indicating test success of the infrared sensing unit 52 (which means that the infrared sensing unit 52 has passed the testing), and stores the primary test result in the storage medium 12.

In sub-step S15, the processing unit 13 controls the arm portion 111 to move based on the second path data D12 of the path dataset D1, such that the arm portion 111 drives the press member 114 of the end portion 112 to move along the second path, thereby pressing the button 54 of the DUT 5. In this embodiment, the press member 114 is a soft foam block with elasticity, which deforms when subjected to a sufficiently large external force, thereby preventing the press member 114 from scratching the button 54.

In sub-step S16, the processing unit 13 determines, based on the status information, whether the control unit 51 has received the press signal from the button 54 indicating that the button 54 has been pressed.

In this embodiment, the processing unit 13 determines whether the control unit 51 has received the press signal by determining, based on the status information, whether the control unit 51 has outputted the communication request within a second time period. The second time period is another time period during which the processing unit 13 controls the arm portion 111 to move based on the second path data D12. When the processing unit 13 determines that the control unit 51 has outputted the communication request within the second time period, the processing unit 13 determines that the control unit 51 has received the press signal, and proceeds to perform sub-step S18. Otherwise, when the processing unit 13 determines that the control unit 51 has not outputted the communication request within the second time period, the processing unit 13 determines that the control unit 51 has not received the press signal, and proceeds to perform sub-step S17.

In sub-step S17, in response to determining that the control unit 51 has not received the press signal, the processing unit 13 generates a secondary test result indicating test failure of the button 54 (which means that the button 54 has failed the testing), stores the secondary test result in the storage medium 12, and ends the testing procedure.

In sub-step S18, in response to determining that the control unit 51 has received the press signal, the processing unit 13 generates the secondary test result indicating test success of the button 54 (which means that the button 54 has passed the testing), stores the secondary test result in the storage medium 12, and ends the testing procedure.

In one example, upon receiving the trigger signal from the infrared sensing unit 52, the control unit 51 switches from the power-saving mode to the normal operation mode, and only in the case that the control unit 51 is operating in the normal operation mode would the control unit 51 output the communication request upon receiving the press signal from the button 54. In other words, in the case that the control unit 51 is operating in the power-saving mode, and the processing unit 13 determines, in sub-step S12, that the control unit 51 has not received the trigger signal, the processing unit 13 ends the testing procedure without continuing to perform sub-steps S15 to S18, and the control unit 51 would not output the communication request, so as to avoid wasting time on ineffective testing of the button 54 of the DUT 5, but the disclosure is not limited to such. In other embodiments, the control unit 51 may output the communication request upon receiving the press signal from the button 54 irrespective of whether the control unit 51 is operating in the normal operation mode. Specifically, as long as the processing unit 13 determines, in sub-step S12, that the control unit 51 has received the trigger signal, the processing unit 13 proceeds to execute sub-step S15 and subsequent sub-steps.

In step S2, the processing unit 13 determines whether a number of times of the testing procedure being executed (step S1) has reached a predetermined number that is pre-stored in the storage medium 12. The predetermined number may be 100 times, but the disclosure is not limited to such.

It should be noted that the number of times of the testing procedure being executed may be recorded by the processing unit 13 as a count number, where the count number is assigned as “1” when the testing procedure is executed for the first time, and each time the testing procedure is repeated, the count number is incremented by 1.

When the processing unit 13 determines that the number of times is less than the predetermined number, the flow returns to step S1 for the processing unit 13 to perform the first testing procedure again.

When the processing unit 13 determines that the first testing procedure has been executed for the predetermined number of times (i.e., the number of times is equal to the predetermined number), the flow proceeds to step S3.

In step S3, the processing unit 13 generates and outputs a test report including the primary test results and the secondary test results, which are obtained by performing the testing procedure for the predetermined number of times. In this embodiment, the test report is presented in a format of a table to display the primary test results and the secondary test results for a user to review. By performing multiple times (e.g., 100) of the testing procedure on the DUT 5, the test report not only presents whether each testing is successful, but may also be used to evaluate whether the DUT 5 has sufficient stability. The processing unit 13 may output the test report by controlling a display unit (e.g., a screen, not shown) to display the test report, transmitting the test report over a network (e.g., Bluetooth®, Wi-Fi, the Internet) to a user device (e.g., a mobile phone, a computer, or a server), or storing the test report in the storage medium 12.

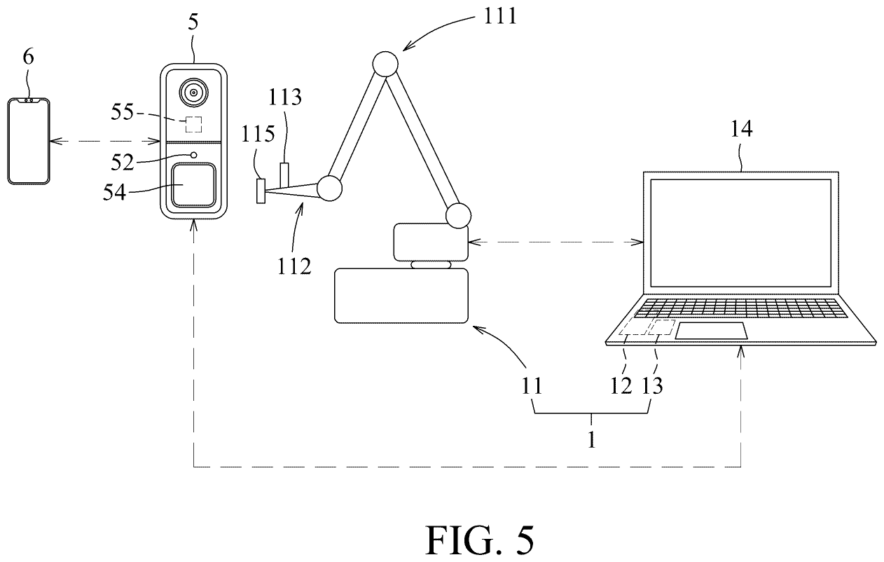

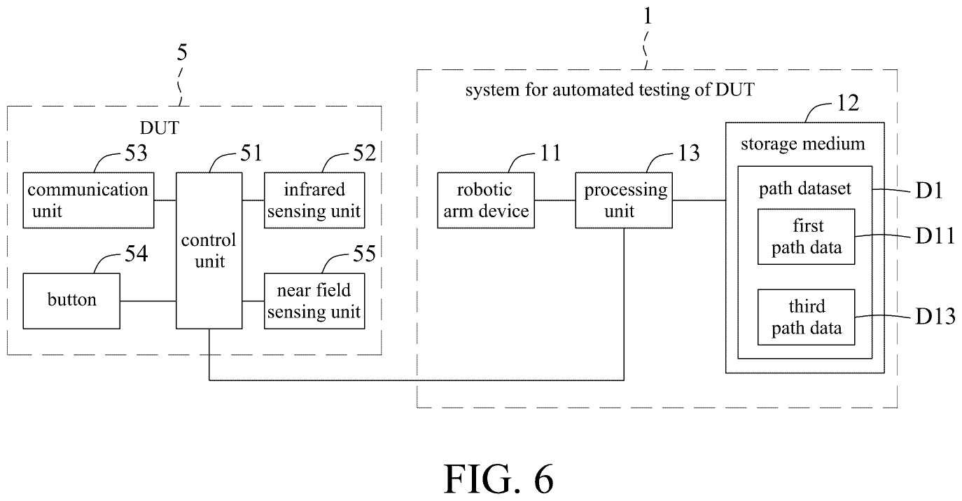

Referring to FIGS. 5 and 6, according to a second embodiment of the disclosure, the system 1 is configured to test whether the infrared sensing function and a near-field communication (NFC) function of the DUT 5 are operating normally. The following description focuses on the differences between this embodiment and the first embodiment.

As shown in FIG. 6, the DUT 5 further includes a near field sensing unit 55 that is electrically connected to the control unit 51. In this embodiment, the near field sensing unit 55 is an NFC module with a reader/writer mode.

As shown in FIG. 5, in this embodiment, the end portion 112 of the robotic arm device 11 includes the heat source 113 and an NFC tag 115 that is able to be sensed by the near field sensing unit 55.

The NFC tag 115 has a control command written therein, where the control command is able to be identified by the control unit 51 of the DUT 5 via the near field sensing unit 55. The control command is used for switching the operation mode of the control unit 51 to a specific operation mode. In this embodiment, the specific operation mode is the power-saving mode. The control unit 51 may be switched from the normal operation mode to the power-saving mode. However, it should be noted that, depending on the control command written in the NFC tag 115 and the functional configuration of the DUT 5, the specific operation mode may be, for example, a management mode that allows a user to perform operation settings on the DUT 5, or a diagnostic/repair mode that facilitates user diagnosis and repair of the DUT 5.

As shown in FIG. 6, in the second embodiment, the path dataset D1 stored in the storage medium 12 includes the first path data D11 and third path data D13. The third path data D13 corresponds to a third path, and is used by the processing unit 13 for controlling the arm portion 111 of the robotic arm device 11 to drive the end portion 112 to move along the third path that is a continuation of the first path (i.e., a beginning of the third path is connected to the end of the first path), such that the NFC tag 115 of the end portion 112 is moved to approach the near field sensing unit 55 and is within a sensing range of the near field sensing unit 55.

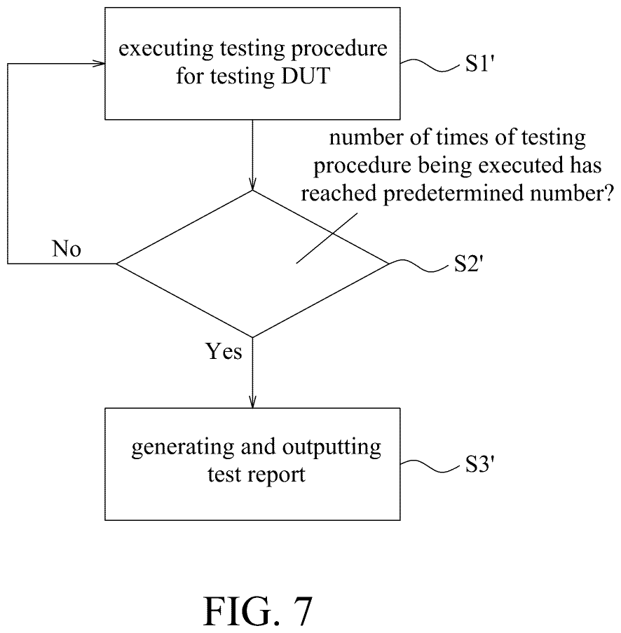

Referring further to FIG. 7, the automated testing method for performing tests on the DUT 5 according to the second embodiment includes steps S1′ to S3′.

In step S1′, the processing unit 13 executes the testing procedure of the second embodiment for testing the DUT 5.

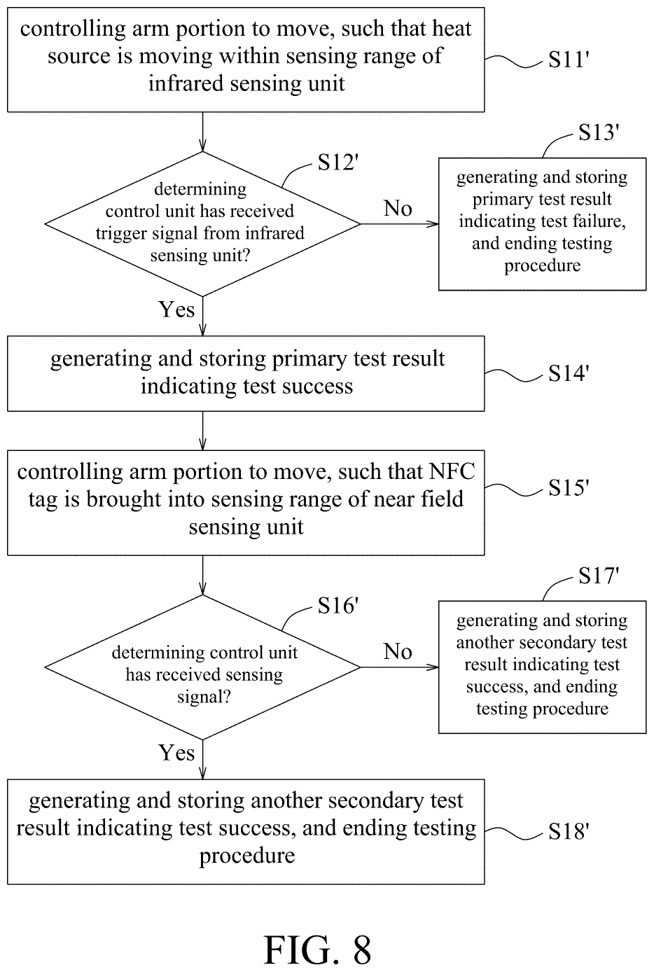

Referring further to FIG. 8, the testing procedure of the second embodiment includes sub-steps S11′ to S18′, where sub-steps S11′ to S14′ are identical to sub-steps S11 to S14 (as shown in FIG. 4), and will not be repeated in the following for the sake of brevity.

In sub-step S15′, the processing unit 13 controls the arm portion 111 to move based on the third path data D13 of the path dataset D1, such that the arm portion 111 drives the NFC tag 115 of the end portion 112 to move along the third path, thereby bringing the NFC tag 115 into the sensing range of the near field sensing unit 55.

In sub-step S16′, the processing unit 13 determines, based on the status information, whether the control unit 51 has received a sensing signal from the near field sensing unit 55 indicating that the near field sensing unit 55 has sensed the NFC tag 115.

In this embodiment, the processing unit 13 determines whether the control unit 51 has received the sensing signal by determining, based on the status information, whether the operation mode of the control unit 51 has been switched within a third time period. The third time period is yet another time period during which the processing unit 13 controls the arm portion 111 to move based on the third path data D13. When the processing unit 13 determines that the operation mode of the control unit 51 has been switched (e.g., switching from the normal operation mode to the power-saving mode, or from a first type of normal operation mode to a second type of normal operation mode) during the third time period, the processing unit 13 determines that the control unit 51 has received the sensing signal, and proceeds to perform sub-step S18′. The first type of normal operation mode and the second type of normal operation mode may be any operation mode such as motion detection mode, do-not-disturb mode, recording mode, and night mode. Otherwise, when the processing unit 13 determines that the operation mode of the control unit 51 has not been switched during the third time period, the processing unit 13 determines that the control unit 51 has not received the sensing signal, and proceeds to perform sub-step S17′. In some embodiments, only when the processing unit 13 determines that the operation mode of the control unit 51 has been switched to the specific operation mode during the third time period would the processing unit 13 determine that the control unit 51 has received the sensing signal, and proceed to perform sub-step S18′. Otherwise, when the processing unit 13 determines that the operation mode of the control unit 51 has not been switched to the specific operation mode during the third time period, the processing unit 13 determines that the control unit 51 has not received the sensing signal, and proceeds to perform sub-step S17′

In sub-step S17′, in response to determining that the control unit 51 has not received the sensing signal, the processing unit 13 generates another secondary test result indicating test failure of the near field sensing unit 55 (which means that the near field sensing unit 55 has failed the testing), stores the another secondary test result in the storage medium 12, and ends the testing procedure.

In sub-step S18′, in response to determining that the control unit 51 has received the sensing signal, the processing unit 13 generates the another secondary test result indicating test success of the near field sensing unit 55 (which means that the near field sensing unit 55 has passed the testing), and stores the another second test result in the storage medium 12, and ends the testing procedure.

In this embodiment, only in the case that the control unit 51 is operating in the normal operation mode would the control unit 51 switch to the specific operation mode upon receiving the sensing signal from the near field sensing unit 55. In other words, in the case that the control unit 51 is operating in the power-saving mode, and the processing unit 13 determines, in sub-step S12′, that the control unit 51 has not received the trigger signal, the processing unit 13 ends the testing procedure without continuing to perform sub-steps S15′ to S18, and the operation mode of the control unit 51 would not be switched to the specific operation mode, so as to avoid wasting time on ineffective testing of the near field sensing unit 55 of the DUT 5.

In step S2′, similar to step S2 of the first embodiment, the processing unit 13 determines whether the number of times of the testing procedure being executed (step S1′) has reached the predetermined number (e.g., 100 times).

When the processing unit 13 determines that the number of times is less than the predetermined number, the flow returns to step S1′ for the processing unit 13 to perform the testing procedure again.

When the processing unit 13 determines that the testing procedure has been executed for the predetermined number of times, the flow proceeds to step S3′.

In step S3′, the processing unit 13 generates and outputs the test report including the primary test results and the another secondary test results, which are obtained by performing the testing procedure for the predetermined number of times.

According to a third embodiment of the disclosure, the testing procedure only includes the steps of testing the infrared sensing unit 52, but does not include the steps of testing the button 54 or the near field sensing unit 55. More specifically, in the third embodiment, the testing procedure only includes sub-steps S11 to S14 in FIG. 4 (identical to sub-steps S11′ to S14′ in FIG. 8), but does not include sub-steps S15 to S18 in FIG. 4, or sub-steps S15′ to S18′ in FIG. 8. Moreover, in the third embodiment, the test report only includes the primary test results related to the infrared sensing unit 52, and does not include the secondary test results related to the button 54 or the near field sensing unit 55. Furthermore, in different applications of the aforementioned embodiments, the DUT 5 may be other types of electronic devices (e.g., surveillance cameras, electronic door locks, burglar alarms, thermometers) that utilize the infrared sensing unit 52 to sense movement of objects.

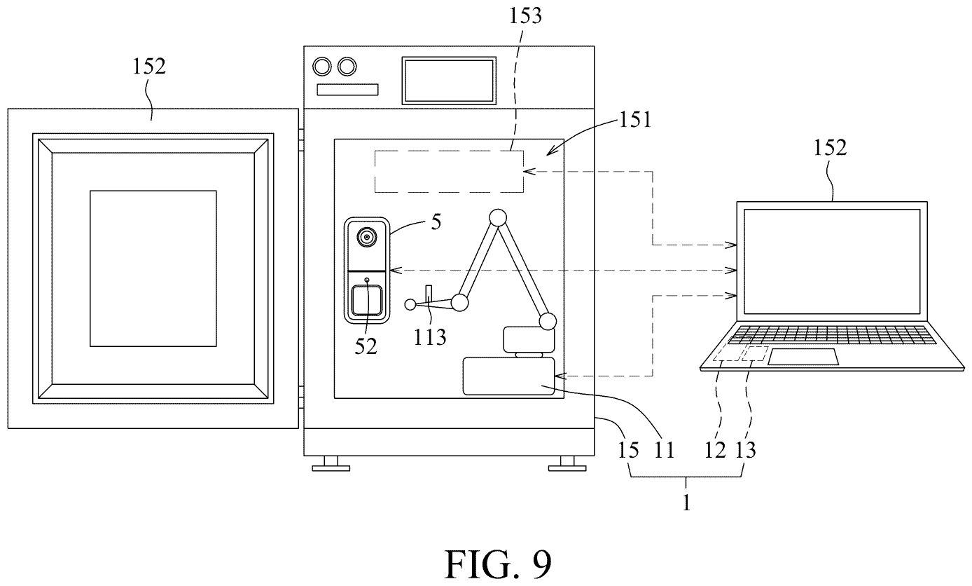

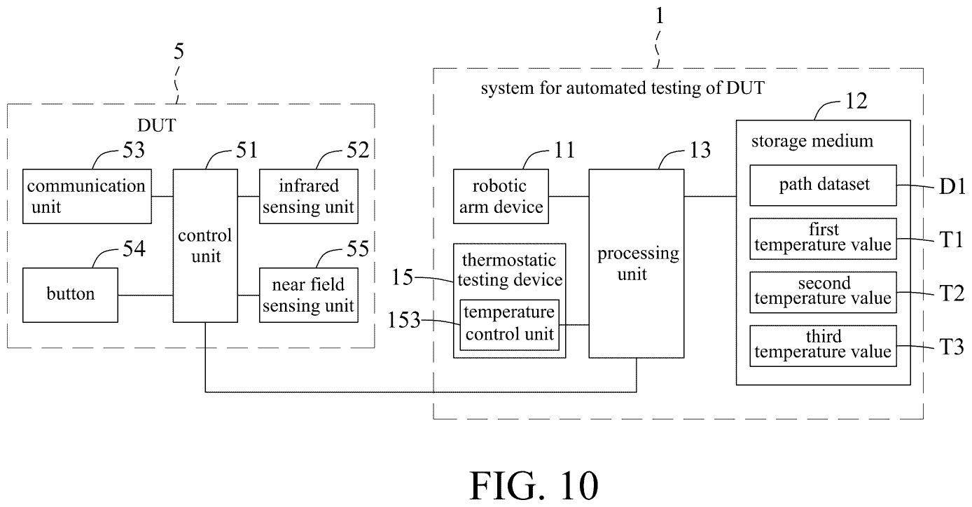

Referring to FIGS. 9 and 10, according to a fourth embodiment of the disclosure, the system 1 is configured to test whether the infrared sensing function of the DUT 5 is operating normally under different temperature conditions. The following description focuses on the differences between this embodiment and the first embodiment.

In this embodiment, the system 1 further includes a thermostatic testing device 15. The thermostatic testing device 15, which may for example be embodied as a programmable constant temperature testing device (also referred to as a temperature test chamber or a thermal test chamber), may include a chamber 151 configured to receive the DUT 5 and the robotic arm device 11 (i.e., the DUT 5 and the robotic arm device 11 may be disposed therein). The thermostatic testing device 15 further includes a door 152 configured to open or close the chamber 151, and a temperature control unit 153 that is electrically connected to the processing unit 13.

The temperature control unit 153 may include a temperature detection module, a heating module (e.g., a heating tube), a refrigeration module (e.g., a refrigerant circulation system implemented by a compressor), and a control module that is electrically connected to the temperature detection module, the heating module, the refrigeration module, and the processing unit 13, which are not shown in the figures. The control module of the temperature control unit 153 is configured to be controlled by the processing unit 13, so as to control the heating module and/or the refrigeration module to change or maintain the temperature inside the chamber 151, thereby forming a constant temperature environment in the chamber 151 when the chamber 151 is closed by the door 152.

As shown in FIG. 9, the DUT 5 is adapted to be disposed in the chamber 151 of the thermostatic testing device 15. Moreover, in this embodiment, the robotic arm device 11 is also disposed in the chamber 151. In other words, the test position is located within the chamber 151.

The storage medium 12 stores a plurality of temperature values that are different from each other. In this embodiment, the temperature values include a first temperature value T1, a second temperature value T2, and a third temperature value T3 that are different from each other (as exemplified in FIG. 10). In one example, the first temperature value T1 is 0°C, the second temperature value T2 is 25°C, and the third temperature value T3 is 45°C, but the disclosure is not limited to such. Additionally, the temperature values may be set according to an operating temperature range of the infrared sensing unit 52 of the DUT 5, and are respectively approximate to or equal to a lower limit value, a medium value, and an upper limit value of the operating temperature range of the infrared sensing unit 52.

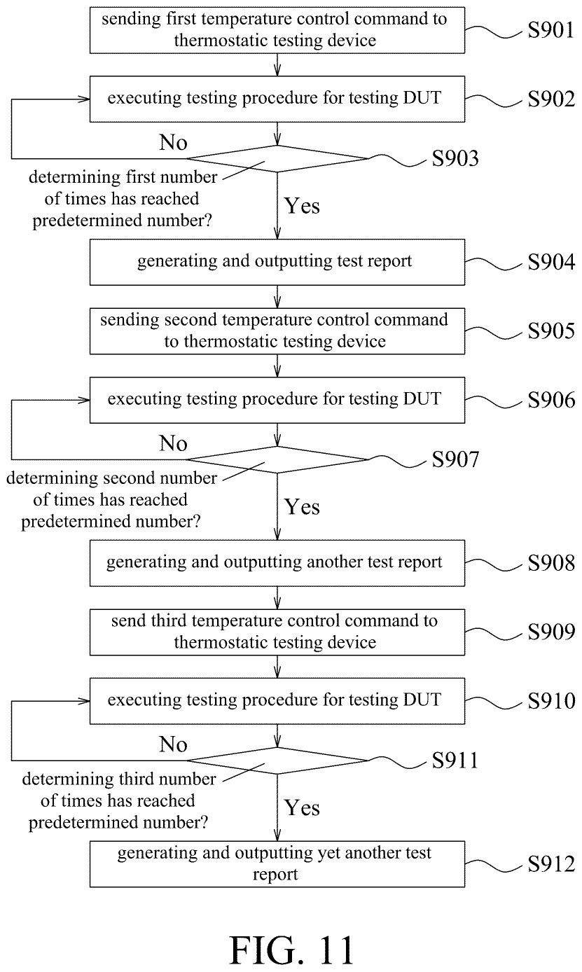

Referring further to FIG. 11, the automated testing method for performing tests on the DUT 5 according to the fourth embodiment includes steps S901 to S912. Specifically, the automated testing method is performed when the chamber 151 is closed by the door 152 (FIG. 9 shows a situation in which the door 152 is opened).

In step S901, the processing unit 13 sends a first temperature control command that includes the first temperature value T1 to the temperature control unit 153 of the thermostatic testing device 15, so that the temperature control unit 153 adjusts and maintains a temperature of the chamber 151 to conform to the first temperature value T1 (e.g., substantially equal to 0 °C) according to the first temperature control command. In this embodiment, the processing unit 13 is further configured to start timing once step S901 has been performed (i.e., once the first temperature control command has been sent), and to proceed to step S902 upon determining that the timing has reached a first waiting period (e.g., 15 minutes, which may be adjustable depending on a speed of temperature adjustment of the temperature control unit 153). As such, the temperature control unit 153 may have enough time to adjust the temperature of the chamber 151 to conform to the first temperature value T1.

In some embodiments, the processing unit 13 may proceed to execute step S902 upon receiving a notification from the temperature control unit 153, where the notification is sent by the temperature control unit 153 upon determining that the temperature of the chamber 151 matches the first temperature value T1, instead of performing timing.

In step S902, the processing unit 13 executes the testing procedure under a condition that the temperature of the chamber 151 conforms to the first temperature value T1. In this embodiment, the testing procedure is identical to the testing procedure of the third embodiment (i.e., includes sub-steps S11 to S14 in FIG. 4, but does not include sub-steps S15 to S18 in FIG. 4 or sub-steps S15′ to S18′ in FIG. 8). That is to say, the testing procedure of the fourth embodiment only includes steps for testing the infrared sensing unit 52, and does not include steps for testing the button 54 (shown in FIGS. 1 and 2) and the near field sensing unit 55 (shown in FIGS. 5 and 6). However, in some embodiments, the testing procedure may include sub-steps S15 to S18 (i.e., steps for testing the button 54), or sub-steps S15′ to S18′ (i.e., steps for testing the near field sensing unit 55).

In step S903, the processing unit 13 determines whether a first number of times of the testing procedure being executed (step S902) has reached the predetermined number. The first number of times refers to the number of times the testing procedure has been executed by the processing unit 13 when the temperature of the chamber 151 conforms to the first temperature value T1 (e.g., 0°C).

When the processing unit 13 determines that the first number of times is less than the predetermined number, the flow returns to step S902 for the processing unit 13 to perform the testing procedure again.

When the processing unit 13 determines that the first number of times has reached the predetermined number of times, the flow proceeds to step S904. In step S904, the processing unit 13 generates and outputs the test report (referred to as “first test report” in this embodiment) to include the primary test results respectively of the predetermined number of times the testing procedure of step S902 is performed. Each of the primary test results indicates whether the infrared sensing unit 52 has passed the test, which in other words indicates whether the infrared sensing unit 52 functions normally in an environment with a temperature matching the first temperature value T1.

In step S905, the processing unit 13 sends a second temperature control command that includes the second temperature value T2 to the temperature control unit 153 of the thermostatic testing device 15, so that the temperature control unit 153 adjusts and maintains the temperature of the chamber 151 to conform to the second temperature value T2 (e.g., 25°C) according to the second temperature control command. In this embodiment, the processing unit 13 is further configured to start timing once step S905 has been performed, and to proceed to step S906 upon determining that the timing has reached a second waiting period (which may be adjustable depending on the speed of temperature adjustment of the temperature control unit 153).

In some embodiments, the processing unit 13 may proceed to execute step S906 upon receiving another notification from the temperature control unit 153, where the another notification is sent by the temperature control unit 153 upon determining that the temperature of the chamber 151 matches the second temperature value T2, instead of performing timing.

In step S906, the processing unit 13 executes the testing procedure again under a condition that the temperature of the chamber 151 conforms to the second temperature value T2. The testing procedure in step S906 is identical to the testing procedure described in step S902.

In step S907, the processing unit 13 determines whether a second number of times of the testing procedure being executed (step S906) has reached the predetermined number. The second number of times refers to the number of times the testing procedure has been executed by the processing unit 13 when the temperature of the chamber 151 conforms to the second temperature value T2 (e.g., 25°C).

When the processing unit 13 determines that the second number of times is less than the predetermined number, the flow returns to step S906 for the processing unit 13 to perform the testing procedure again.

When the processing unit 13 determines that the second number of times has reached the predetermined number of times, the flow proceeds to step S908. In step S908, the processing unit 13 generates and outputs another test report (referred to as “second test report” in this embodiment) to include the primary test results respectively of the predetermined number of times the testing procedure of step S906 is performed. Each of the primary test results indicates whether the infrared sensing unit 52 has passed the test, which in other words indicates whether the infrared sensing unit 52 functions normally in an environment with a temperature matching the second temperature value T2.

In step S909, the processing unit 13 sends a third temperature control command that includes the third temperature value T3 to the temperature control unit 153 of the thermostatic testing device 15, so that the temperature control unit 153 adjusts and maintains the temperature of the chamber 151 to conform to the third temperature value T3 (e.g., 45°C) according to the third temperature control command. In this embodiment, the processing unit 13 is further configured to start timing once step S909 has been performed, and to proceed to step S910 upon determining that the timing has reach a third waiting period (which may be adjustable depending on the speed of temperature adjustment of the temperature control unit 153).

In some embodiments, the processing unit 13 may proceed to execute step S910 upon receiving yet another notification from the temperature control unit 153, where the yet another notification is sent by the temperature control unit 153 upon determining that the temperature of the chamber 151 matches the third temperature value T3, instead of performing timing.

In step S910, the processing unit 13 executes the testing procedure again under a condition that the temperature of the chamber 151 conforms to the third temperature value T3. The testing procedure in step S910 is identical to the testing procedure described in step S902.

In step S911, the processing unit 13 determines whether a third number of times of the testing procedure being executed (step S910) has reached the predetermined number. The third number of times refers to the number of times the testing procedure has been executed by the processing unit 13 when the temperature of the chamber 151 conforms to the third temperature value T3 (e.g., 45°C).

When the processing unit 13 determines that the third number of times is less than the predetermined number, the flow returns to step S910 for the processing unit 13 to perform the testing procedure again.

When the processing unit 13 determines that the third number of times has reached the predetermined number of times, the flow proceeds to step S912. In step S912, the processing unit 13 generates and outputs yet another test report (referred to as “third test report” in this embodiment) to include the primary test results respectively of the predetermined number of times the testing procedure of step S910 is performed. Each of the primary test results indicates whether the infrared sensing unit 52 has passed the test, which in other words indicates whether the infrared sensing unit 52 functions normally in an environment with a temperature matching the third temperature value T3.

In some embodiments, steps S904 and S908 may be merged into step S912. That is to say, the processing unit 13 may first execute steps S901 to S903, steps S905 to S907 and steps S909 to S911 in sequence, and then generate and output the first test report, the second test report, and the third test report together (either separately or combined).

According to the fourth embodiment, the system 1 may automatically adjust the temperature inside the chamber 151 and repeatedly execute the testing procedure on the DUT 5 inside the chamber 151 under each of the different environmental temperatures, and output the test report corresponding to each of the temperatures. It should be noted that, since the infrared sensing function for detecting movement of an object is operated based on an infrared thermal radiation emitted by the object, the infrared sensing unit 52 is more susceptible to influences from environmental temperature than that of the button 54 and the near field sensing unit 55. Based on the above, the fourth embodiment may test whether the infrared sensing function of the DUT 5 is operable under different temperatures by using temperature as a variable, thereby providing more comprehensive tests.

In summary, by performing the automated testing method on the DUT 5, the system 1 may automatically test the infrared sensing function of the DUT 5 using the robotic arm device 11 through the testing procedure, and may further test the button 54 and/or the near field communication function of the DUT 5. Primary test results and secondary test results may be generated to indicate test failure or test success based on the status information of the DUT 5, and a test report may be further generated and outputted to include the primary test results and the secondary test results when the number of times of the testing procedure being executed has reached the predetermined number. The system 1 of the disclosure provides an efficient and reliable testing mechanism for the DUT 5, and does not require human intervention during the testing procedure, thereby achieving the purpose of the present disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An automated testing method executed by a system for performing tests on a device under test (DUT), the DUT including an infrared sensing unit and a control unit, the system including a robotic arm device, a storage medium that stores a path dataset, and a processing unit that is electrically connected to the storage medium and the robotic arm device, and that is adapted to be electrically connected to the control unit, the robotic arm device including an arm portion that is configured to be controlled by the processing unit to move, and an end portion that is disposed on the arm portion so as to be driven by the arm portion and that includes a heat source, the method comprising steps of:
A) the processing unit executing a testing procedure for testing the DUT, wherein the testing procedure includes sub-steps of
a1) controlling the arm portion to move based on the path dataset, such that the heat source of the end portion is moved within a sensing range of the infrared sensing unit,
a2) receiving status information that is generated by the control unit, and determining, based on the status information, whether the control unit has received a trigger signal from the infrared sensing unit indicating that the infrared sensing unit has sensed an object,
a3) in response to determining that the control unit has not received the trigger signal, generating a primary test result indicating test failure, and storing the primary test result in the storage medium, and
a4) in response to determining that the control unit has received the trigger signal, generating the primary test result indicating test success, and storing the primary test result in the storage medium; and
B) after the testing procedure has ended, the processing unit generating and outputting a test report that includes the primary test result.

2. The method as claimed in claim 1, the system 1 further including a thermostatic testing device that is electrically connected to the processing unit, and that includes a chamber configured to receive the DUT and the robotic arm device,
the method further comprising, before step A), a step C) of the processing unit controlling the thermostatic testing device to adjust a temperature of the chamber according to a first temperature value, so as to cause the temperature of the chamber to conform to the first temperature value, wherein in step A), the processing unit executes the testing procedure under a condition that the temperature of the chamber conforms to the first temperature value;
the method further comprising steps of, after step A):
D) the processing unit controlling the thermostatic testing device to adjust the temperature of the chamber according to a second temperature value that is different from the first temperature value, so as to cause the temperature of the chamber to conform to the second temperature value,
E) the processing unit re-executing the testing procedure under a condition that the temperature of the chamber conforms to the second temperature value, and
F) after step E), the processing unit generating and outputting another test report after re-executing the testing procedure.

3. The method as claimed in claim 1, the DUT further including a button configured to receive an input via depression, the end portion of the robotic arm device further including a press member made of a soft material, wherein in step A), the testing procedure further includes, after sub-step a4), sub-steps of:
a5) controlling the arm portion to move based on the path dataset, such that the press member of the end portion is moved to press the button of the DUT,
a6) determining, based on the status information, whether the control unit has received a press signal from the button indicating that the button has been pressed,
a7) in response to determining that the control unit has not received the press signal, generating a secondary test result indicating test failure, and storing the secondary test result in the storage medium, and
a8) in response to determining that the control unit has received the press signal, generating the secondary test result indicating test success, and storing the secondary test result in the storage medium;
wherein in step B), the test report further includes the secondary test result.

4. The method as claimed in claim 3, the DUT further including a communication unit that is configured to establish a communication connection with a user-end device, wherein sub-step a6) includes:
determining, based on the status information, whether the control unit has outputted a communication request;
in response to determining that the control unit has outputted the communication request, determining that the control unit has received the press signal; and
in response to determining that the control unit has not outputted the communication request, determining that the control unit has not received the press signal;
wherein the communication request is transmitted through the communication unit, and is for requesting the user-end device to permit the communication connection to be established with the DUT.

5. The method as claimed in claim 1, the DUT further including a near field sensing unit, the end portion of the robotic arm device further including a near field communication (NFC) tag that is able to be sensed by the near field sensing unit, wherein in step A), the testing procedure further includes, after sub-step a4), sub-steps of:
a9) controlling the arm portion to move based on the path dataset, such that the NFC tag of the end portion is moved to approach the near field sensing unit of the DUT;
a10) determining, based on the status information, whether the control unit has received a sensing signal from the near field sensing unit indicating that the near field sensing unit has sensed the NFC tag;
a11) in response to determining that the control unit has not received the sensing signal, generating a secondary test result indicating test failure, and storing the secondary test result in the storage medium; and
a12) in response to determining that the control unit has received the sensing signal, generating the secondary test result indicating test success, and storing the secondary test result in the storage medium;
wherein in step (B), the test report further includes the secondary test result.

6. The method as claimed in claim 5, wherein sub-step a6) includes:
determining, based on the status information, whether an operation mode of the control unit has been switched;
in response to determining that the operation mode of the control unit has been switched, determining that the control unit has received the sensing signal; and
in response to determining that the operation mode of the control unit has not been switched, determining that the control unit has not received the sensing signal.

7. A system for automated testing of a device under test (DUT), the DUT including an infrared sensing unit and a control unit, the system comprising:
a processing unit configured to be electrically connected to the control unit;
a storage medium electrically connected to said processing unit and storing a path dataset; and
a robotic arm device electrically connected to said processing unit, and including an arm portion that is configured to be controlled by the processing unit to move, and an end portion that is disposed on the arm portion so as to be driven by the arm portion, and that includes a heat source;
said processing unit being configured to execute a testing procedure for testing the DUT by performing steps of
a1) controlling said arm portion to move based on the path dataset, such that said heat source of said end portion is moved within a sensing range of the infrared sensing unit,
a2) receiving status information that is generated by the control unit, and determining, based on the status information, whether the control unit has received a trigger signal from the infrared sensing unit indicating that the infrared sensing unit has sensed an object,
a3) in response to determining that the control unit has not received the trigger signal, generating a primary test result indicating test failure, and storing the primary test result in said storage medium, and
a4) in response to determining that the control unit has received the trigger signal, generating the primary test result indicating test success, and storing the primary test result in said storage medium; and
said processing unit being further configured to, after the testing procedure has ended, generate and output a test report that includes the primary test result.

8. The system as claimed in claim 7, further comprising a thermostatic testing device that is electrically connected to said processing unit, and that includes a chamber configured to receive the DUT and the robotic arm device, wherein:
said processing unit is further configured to, before executing the testing procedure, control said thermostatic testing device to adjust a temperature of said chamber according to a first temperature value, so as to cause the temperature of said chamber to conform to the first temperature value;
said processing unit is configured to execute the testing procedure under a condition that the temperature of said chamber conforms to the first temperature value;
said processing unit is further configured to, after executing the testing procedure:
control said thermostatic testing device to adjust the temperature of said chamber according to a second temperature value that is different from the first temperature value, so as to cause the temperature of said chamber to conform to the second temperature value,
re-execute the testing procedure under a condition that the temperature of said chamber conforms to the second temperature value, and
generate and output another test report after re-executing the testing procedure.

9. The system as claimed in claim 7, the DUT further including a button configured to receive an input via depression, wherein:
said end portion of said robotic arm device further includes a press member made of a soft material;
said processing unit is configured to execute the testing procedure further by performing steps of, after a4),
a5) controlling the arm portion to move based on the path dataset, such that the press member of the end portion is moved to press the button of the DUT,
a6) determining, based on the status information, whether the control unit has received a press signal from the button indicating that the button has been pressed,
a7) in response to determining that the control unit has not received the press signal, generating a secondary test result indicating test failure, and storing the secondary test result in the storage medium, and
a8) in response to determining that the control unit has received the press signal, generating the secondary test result indicating test success, and storing the secondary test result in the storage medium;
wherein said processing unit is configured to generate the test report to further include the secondary test result.

10. The system as claimed in claim 9, the DUT further including a communication unit that is configured to establish a communication connection with a user-end device, wherein said processing unit is configured to perform step a6) by:
determining, based on the status information, whether the control unit has outputted a communication request;
in response to determining that the control unit has outputted the communication request, determining that the control unit has received the press signal; and
in response to determining that the control unit has not outputted the communication request, determining that the control unit has not received the press signal;
wherein the communication request is transmitted through the communication unit, and is for requesting the user-end device to permit the communication connection to be established with the DUT.

11. The system as claimed in claim 7, the DUT further including a near field sensing unit, said end portion of said robotic arm device further including a near field communication (NFC) tag that is able to be sensed by the near field sensing unit, wherein said processing unit is configured to execute the testing procedure further by performing steps of, after a4):
a9) controlling said arm portion to move based on the path dataset, such that said NFC tag of said end portion is moved to approach the near field sensing unit of the DUT;
a10) determining, based on the status information, whether the control unit has received a sensing signal from the near field sensing unit indicating that the near field sensing unit has sensed said NFC tag;
a11) in response to determining that the control unit has not received the sensing signal, generating a secondary test result indicating test failure, and storing the secondary test result in said storage medium; and
a12) in response to determining that the control unit has received the sensing signal, generating the secondary test result indicating test success, and storing the secondary test result in said storage medium;
wherein said processing unit is configured to generate the test report to further include the secondary test result.

12. The system as claimed in claim 11, wherein said processing unit is configured to perform step a6) by:
determining, based on the status information, whether an operation mode of the control unit has been switched;
in response to determining that the operation mode of the control unit has been switched, determining that the control unit has received the sensing signal; and
in response to determining that the operation mode of the control unit has not been switched, determining that the control unit has not received the sensing signal.
